(19) United States
(12) Patent Application Publication
(10) Pub. No.: US 2022/0252395 A1
(43) Pub. Date: Aug. 11, 2022

(54) Methods And Systems For Accurate Measurement Of Deep Structures Having Distorted Geometry

(71) Applicant: KLA Corporation, Milpitas, CA (US)

(72) Inventors: John J. Hench, Los Gatos, CA (US); Thaddeus Gerard Dziura, San Jose, CA (US)

(21) Appl. No.: 17/590,116

(22) Filed: Feb. 1, 2022

Related U.S. Application Data
(60) Provisional application No. 63/147,758, filed on Feb. 10, 2021.

(51) Int. Cl. G01B 15/04; H01L 21/66

(52) U.S. Cl. CPC G01B 15/04; H01L 22/26

(57) ABSTRACT

Methods and systems for estimating values of geometric parameters characterizing in-plane, distorted shapes of high aspect ratio semiconductor structures based on x-ray scatterometry measurements are presented herein. A parameterized geometric model captures the scattering signature of in-plane, non-elliptical distortions in hole shape. By increasing the number of independent parameters employed to describe the in-plane shape of hole structures the model fit to the actual shape of high aspect ratio structures is improved. In one aspect, a geometrically parameterized measurement model includes more than two degrees of freedom to characterize the in-plane shape of a measured structure. In some embodiments, the geometric model includes a closed curve having three degrees of freedom or more. In some embodiments, the geometric model includes a piecewise assembly of two or more conic sections. Independent geometric model parameters are expressed as functions of depth to capture shape variation through the structure.

### CROSS REFERENCE TO RELATED APPLICATION

The present application for patent claims priority under 35 U.S.C. § 119 from U.S. provisional patent application Ser. No. 63/147,758, entitled “Accurate Modelling of Lithographic and Etch Shapes using Distorted Ellipses,” filed Feb. 10, 2021, the subject matter of which is incorporated herein by reference in its entirety.

### TECHNICAL FIELD

The described embodiments relate to metrology systems and methods, and more particularly to methods and systems for improved measurement of deep semiconductor structures fabricated by repeated lithographic and etch fabrication process steps.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. A number of metrology based techniques including scatterometry and reflectometry implementations and associated analysis algorithms are commonly used to characterize critical dimensions, film thicknesses, composition and other parameters of nanoscale structures. X-ray scatterometry techniques offer the potential for high throughput without the risk of sample destruction.

Traditionally, optical scatterometry critical dimension (SCR) measurements are performed on targets consisting of thin films and/or repeated periodic structures. During device fabrication, these films and periodic structures typically represent the actual device geometry and material structure or an intermediate design. As devices (e.g., logic and memory devices) move toward smaller nanometer-scale dimensions, characterization becomes more difficult. Devices incorporating complex three-dimensional geometry and materials with diverse physical properties contribute to characterization difficulty. For example, modern memory structures are often high-aspect ratio, three-dimensional structures that make it difficult for optical radiation to penetrate to the bottom layers. Optical metrology tools utilizing infrared to visible light can penetrate many layers of translucent materials, but longer wavelengths that provide good depth of penetration do not provide sufficient sensitivity to small anomalies. In addition, the increasing number of parameters required to characterize complex structures (e.g., FinFETs), leads to increasing parameter correlation. As a result, the parameters characterizing the target often cannot be reliably decoupled with available measurements.

In one example, longer wavelengths (e.g. near infrared) have been employed in an attempt to overcome penetration issues for 3D FLASH devices that utilize polysilicon as one of the alternating materials in the stack. However, the mirror like structure of 3D FLASH intrinsically causes decreasing light intensity as the illumination propagates deeper into the film stack. This causes sensitivity loss and correlation issues at depth. In this scenario, optical SCD is only able to successfully extract a reduced set of metrology dimensions with high sensitivity and low correlation.

In another example, opaque, high-k materials are increasingly employed in modern semiconductor structures. Optical radiation is often unable to penetrate layers constructed of these materials. As a result, measurements with thin-film scatterometry tools such as ellipsometers or reflectometers are becoming increasingly challenging.

In response to these challenges, more complex optical metrology tools have been developed. For example, tools with multiple angles of illumination, shorter illumination wavelengths, broader ranges of illumination wavelengths, and more complete information acquisition from reflected signals (e.g., measuring multiple Mueller matrix elements in addition to the more conventional reflectivity or ellipsometric signals) have been developed. However, these approaches have not reliably overcome fundamental challenges associated with measurement of many advanced targets (e.g., complex 3D structures, structures smaller than 10 nm, structures employing opaque materials) and measurement applications (e.g., line edge roughness and line width roughness measurements).

Optical methods may provide non-destructive tracking of process variable between process steps, but regular calibration by destructive methods is required to maintain accuracy in the face of process drift, which optical methods cannot independently distinguish.

Atomic force microscopes (AFM) and scanning-tunneling microscopes (STM) are able to achieve atomic resolution, but they can only probe the surface of the specimen. In addition, AFM and STM microscopes require long scanning times. Scanning electron microscopes (SEM) achieve intermediate resolution levels, but are unable to penetrate structures to sufficient depth. Thus, high-aspect ratio holes are not characterized well. In addition, the required charging of the specimen has an adverse effect on imaging performance. X-ray reflectometers also suffer from penetration issues that limit their effectiveness when measuring high aspect ratio structures.

To overcome penetration depth issues, traditional imaging techniques such as TEM, SEM etc., are employed with destructive sample preparation techniques such as focused ion beam (FIB) machining, ion milling, blanket or selective etching, etc. For example, transmission electron microscopes (TEM) achieve high resolution levels and are able to probe arbitrary depths, but TEM requires destructive sectioning of the specimen. Several iterations of material removal and measurement generally provide the information required to measure the critical metrology parameters throughout a three dimensional structure. But, these techniques require sample destruction and lengthy process times. The complexity and time to complete these types of measurements introduces large inaccuracies due to drift of etching and metrology steps because the measurement results become available long after the process has been completed on the wafer under measurement. Thus, the measurement results are subject to biases from further processing and delayed feedback. In addition, these techniques require numerous iterations which introduce registration errors. In summary, device yield is negatively impacted by long and destructive sample preparation required for SEM and TEM techniques.

In general, there are many methods of process monitoring using combinations of optical, acoustic and electron beam tools. These techniques measure the device directly, specially designed targets, or specific monitor wafers. However, the inability to measured parameters of interest of high aspect ratio structures in a cost effective and timely manner results in low yield, particularly in the memory sector of a wafer.

Transmission, Small-Angle X-Ray Scatterometry (T-SAXS) systems employing photon at a hard X-ray energy level (>15 keV) have shown promise to address challenging measurement applications. Various aspects of the application of SAXS technology to the measurement of critical dimensions (CD-SAXS) and overlay (OVL-SAXS) are described in 1) U.S. Pat. No. 7,929,667 to Zhuang and Fielden, entitled “High-brightness X-ray metrology,” 2) U.S. Patent Publication No. 2014/0019097 by Bakeman, Shchegrov, Zhao, and Tan, entitled “Model Building And Analysis Engine For Combined X-Ray And Optical Metrology,” 3) U.S. Patent Publication No. 2015/0117610 by Veldman, Bakeman, Shchegrov, and Mieher, entitled “Methods and Apparatus For Measuring Semiconductor Device Overlay Using X-Ray Metrology,” 4) U.S. Patent Publication No. 2016/0202193 by Hench, Shchegrov, and Bakeman, entitled “Measurement System Optimization For X-Ray Based Metrology,” 5) U.S. Patent Publication No. 2017/0167862 by Dziura, Gellineau, and Shchegrov, entitled “X-ray Metrology For High Aspect Ratio Structures,” and 6) U.S. Patent Publication No. 2018/0106735 by Gellineau, Dziura, Hench, Veldman, and Zalubovsky, entitled “Full Beam Metrology for X-Ray Scatterometry Systems,” the content of each of these documents is incorporated herein by reference in its entirety. The aforementioned patent documents are assigned to KLA-Tencor Corporation, Milpitas, Calif. (USA). In addition, U.S. Pat. No. 9,606,073 to Mazor, et al. entitled “X-ray scatterometry apparatus” describes various aspects of the application of SAXS technology to semiconductor structures, the content of which is incorporated herein by reference in its entirety.

SAXS has also been applied to the characterization of materials and other non-semiconductor related applications. Exemplary systems have been commercialized by several companies, including Xenocs SAS (www.xenocs.com), Bruker Corporation (www.bruker.com), and Rigaku Corporation (www.rigaku.com/en). Both Bruker and Rigaku offer small angle x-ray scatterometry systems and wide angle x-ray scatterometery systems named “Nanostar” and “Nanopix”, respectively. These systems include adjustable sample-to-detector distance.

Research on CD-SAXS metrology of semiconductor structures is also described in scientific literature. Most research groups have employed high-brightness X-ray synchrotron sources which are not suitable for use in a semiconductor fabrication facility due to their immense size, cost, etc. One example of such a system is described in the article entitled “Intercomparison between optical and x-ray scatterometry measurements of FinFET structures” by Lemaillet, Germer, Kline et al., Proc. SPIE, v.8681, p. 86810Q (2013), the content of each of these documents is incorporated herein by reference in its entirety. More recently, a group at the National Institute of Standards and Technology (NIST) has initiated research employing compact and bright X-ray sources similar those described in U.S. Pat. No. 7,929,667. This research is described in an article entitled “X-ray scattering critical dimensional metrology using a compact x-ray source for next generation semiconductor devices,” J. Micro/Nanolith. MEMS MOEMS 16(1), 014001 (January-March 2017), the content of each of these documents is incorporated herein by reference in its entirety.

X-ray scatterometry based metrology techniques are indirect methods of measuring physical properties of a specimen under measurement. In most cases, the raw measurement signals cannot be used to directly determine the physical properties of the specimen. Instead, a measurement model is employed to estimate the values of one or more parameters of interest characterizing the structure under measurement based on the raw measurement signals. In general, a physics-based measurement model or a machine learning based measurement model is required to determine the physical properties of the specimen based on the raw measurement signals (e.g., detected intensities, Iₘₑₐₛ).

In some examples, a physics-based measurement model is created that attempts to predict the raw measurement signals based on assumed values of one or more model parameters. As illustrated in equation (1), the measurement model includes parameters associated with the metrology tool itself, e.g., system parameters (P_{system}), and parameters associated with the specimen under measurement. When solving for parameters of interest, some specimen parameters are treated as fixed valued (P_{spec-fixed}) and other specimen parameters of interest are floated (P_{spec-float}), i.e., resolved based on the raw measurement signals.

$${I}_{m o d e l} = f ( {P}_{system} , {P}_{spec - fixed} , {P}_{spec - float} ) \qquad ( 1 )$$

System parameters are parameters used to characterize the metrology tool (e.g., an x-ray scatterometer). Exemplary system parameters include angle of incidence (AOI), azimuth angle (Az), illumination wavelengths, etc. Specimen parameters are parameters used to characterize the specimen (e.g., material and geometric parameters characterizing the structure(s) under measurement). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the system parameters and many of the specimen parameters are treated as known, fixed valued parameters. However, the values of one or more of the specimen parameters are treated as unknown, floating parameters of interest.

In some examples, the values of the floating parameters of interest are resolved by an iterative process (e.g., regression) that produces the best fit between theoretical predictions and experimental data. The values of the unknown, floating parameters of interest are varied and the model output values (e.g., I_{model}) are calculated and compared to the raw measurement data, Iₘₑₐₛ, in an iterative manner until a set of specimen parameter values are determined that results in a sufficiently close match between the model output values and the experimentally measured values. In some other examples, the floating parameters are resolved by a search through a library of pre-computed solutions to find the closest match.

In recent articles, authors report a number of geometrical distortions observed in deep channel holes fabricated by state of the art semiconductor fabrication equipment. Such deep channel holes are common structural elements of both NAND and DRAM memory devices. An exemplary article is entitled, “Plasma etching of high aspect ratio features in SiO2 using Ar/C4F8/O2 mixtures: A computational investigation” authored by Shuo Huang, et al., the content of which is incorporated herein by reference in its entirety.

Various types of distortions arise when attempting to etch a relatively deep cylindrical hole in a device. Some distortions include variation in critical dimension (CD) and variation in orientation of the hole profile as a function of height. Other distortions include in-plane shape distortions that result in an in-plane hole shape that is non-elliptical in nature. FIG. 1 is an illustration of a portion of a figure (FIG. 21) present in the aforementioned article entitled, “Plasma etching of high aspect ratio features in SiO2 using Ar/C4F8/O2 mixtures: A computational investigation.” FIG. 1 depicts five images 10A-E of a hole structure. Each image is a horizontal slice of the hole structure at a different depth from the surface of the hole structure. The hole structure is fabricated through material layers of an anti-reflective coating. Image 10A illustrates the shape of the hole etched through a photoresist material. Images 10B-E illustrate the shape of the hole etched through a silicon oxide material. As depicted in FIG. 1, the shape of the hole structure varies as a function of depth and, more importantly, the actual, in-plane hole shape is non-elliptical in nature particularly at greater depths within the hole structure.

As depicted in FIG. 1, the non-elliptical distortion tends to grow as a function of depth of the hole. Near the top of the etched hole structure, the hole is well approximated as a circle. However, near the bottom of the etched hole structure, the hole is severely distorted such that a simple ellipse shape does not closely approximate the hole shape.

Typically, a measurement model associated with an X-ray scatterometry based measurement describes an etched hole shape in a semiconductor device as a simple ellipse. At any given height in the device, the ellipse is described by its eccentricity, e, in a nominal canonical axis (e.g., x or y axis), its center location (e.g., x0 and y0) and its rotation, θ, relative to the x axis. These parameters vary as a function of height, z, perpendicular to the wafer surface. In this manner, the model captures changes of in-plane shape as a function of height of the structure.

A simple description of an elliptical shape, centered at an origin with canonical axes described by the Cartesian x and y is illustrated by equations (2A)-(2B).

$$\begin{matrix}x = r e cos θ & ( 2 A ) \\ y = r sin θ & ( 2 B )\end{matrix}$$

As illustrated by equations (2A)-(2B), the traditional model of an ellipse is a closed curve having two degrees of freedom, i.e., two independent parameters that define the shape of the curve in a two dimensional plane. In this example, the two degrees of freedom are the nominal radius, r, and the eccentricity, e.

Unfortunately, an elliptical shape model such as the model illustrated in equations (2A)-(2B) does not account for in-plane distortions of a non-elliptical nature and also fails to parameterize deviations from a nominal elliptical shape in a meaningful way. Current measurement model implementations introduce systematic errors in the signal residual when non-linear components are present. In some examples, these systematic errors bias the solution of a parametric regression. This reduces the repeatability, match, and precision of estimated values of parameters of interest, e.g., critical dimensions, of the structure.

In summary, ongoing reductions in feature size and increased depth of many semiconductor structures imposes difficult requirements on metrology systems. Thus, improved metrology systems and methods are desired to measure high aspect ratio structures to maintain high device yield.

### SUMMARY

Methods and systems for estimating values of geometric parameters characterizing in-plane, distorted shapes of high aspect ratio semiconductor structures based on x-ray scatterometry measurements are presented herein. In some embodiments, the one or more structures under measurement are deep hole structures fabricated by a series of lithographic and etch steps.

In some examples, scatterometry based metrology tools are sensitive to small changes in hole shape throughout the depth of a hole structure, including in-plane, non-elliptical distortions in hole shape. A measurement model includes a parameterized geometric model that captures the scattering signature of the distorted shapes. By increasing the number of parameters employed to describe the in-plane shape of hole structures the resulting geometric model fits the actual shape of the hole structure, including shape errors induced by non-ideal lithographic and etch processes.

In one aspect, a scatterometry based measurement model includes a geometrically parameterized measurement model having more than two degrees of freedom to characterize the in-plane shape of a measured structure.

In some embodiments, the geometric model employed to characterize the in-plane shape of a measured hole structure at a particular depth includes a closed curve having three degrees of freedom or more, i.e., three or more independent parameters define the shape of the curve in a two dimensional plane.

In some embodiments, the geometric model employed to characterize the in-plane shape of a measured hole structure at a particular depth is a closed curve comprising a piecewise assembly of two or more conic sections, e.g., elliptical, parabolic, hyperbolic sections. In these embodiments, each conic section is defined by at least one independent parameter, i.e., each conic section has at least one degree of freedom. Moreover, a piecewise assembly of conic sections defined by a total of more than two independent parameters, i.e., more than two degrees of freedom, is employed to describe the in-plane shape of one or more hole structures at a particular depth.

In general, the independent parameters of a geometric model describing an in-plane hole shape are expressed as functions of depth through the structure. In this manner, the geometric model captures the real variation of the in-plane shape of processed semiconductor devices as a function of depth. In a typical patterning process, holes in resist are approximately circular with minimal or very small distortion. However, the process control of an etch tool is limited. As a result, the distortion changes with depth as the etch process transfers the lithographic pattern to the semiconductor layer. The ability to accurately describe the shape variation as function of depth leads to a more accurate fit between model and measured data, and consequently, improved estimates of shape parameter values.

In another aspect, process corrections are determined based on the measured values of the parameters of interest and the corrections are communicated to the process tool to change one or more process control parameters of the process tool (e.g., lithography tool, etch tool, deposition tool, etc.).

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 depicts an illustration of images of several horizontal slices of a hole structure at different depths from the wafer surface.

FIG. 2 depicts an exemplary wafer measurement system 100 for monitoring of an etch process based on x-ray scatterometry measurements of semiconductor structures disposed on a wafer.

FIG. 3 is a diagram illustrative of an exemplary model building and analysis engine 180.

FIG. 4 is a diagram illustrative of shapes described by a first order circular function and a second order circular function in one example.

FIG. 5 is a diagram illustrative of a three dimensional plot of signal error at the detector in one example.

FIG. 6 is a diagram illustrative of shapes described by a first order circular function, a second order circular function, and piecewise assembly of four conic sections in one example

FIGS. 7A-7C depict an isometric view, a top view, and a cross-sectional view, respectively, of a typical 3D FLASH memory device subject to measurement as described herein.

FIG. 8 depicts an exemplary wafer processing system 200 for monitoring of an etch process based on reflective x-ray scatterometry measurements of semiconductor structures disposed on a wafer.

FIG. 9 illustrates a flowchart of a method 300 for measuring high aspect ratio structures based on small angle X-Ray scatterometry measurements.

### DETAILED DESCRIPTION

Reference will now be made in detail to background examples and some embodiments of the invention, examples of which are illustrated in the accompanying drawings.

Methods and systems for estimating values of geometric parameters characterizing high aspect ratio semiconductor structures based on x-ray scatterometry measurements are presented herein. More specifically, a measurement model employed to perform scatterometry based measurements includes a parameterized geometric model characterizing in-plane, distorted shapes of one or more hole structures under measurement.

Modern Small-Angle X-ray Scatterometry (SAXS) metrology tools are sensitive to small changes in hole shape throughout the depth of a hole structure, including in-plane, non-elliptical distortions in hole shape. Traditionally, a simple ellipse is employed as the fundamental shape function to describe the geometry of many semiconductor devices, e.g., DRAM structures, 3D NAND structures, etc., at any given height in the structure. Unfortunately, the in-plane shape of many real devices is distorted significantly from the shape of a simple ellipse. As a result, traditional measurement models fail to capture the scattering signature of these distorted shapes that is present in the measurement signals generated by modern SAXS metrology tools.

Measurement accuracy of hole shaped structures throughout their depth is significantly improved by employing a geometric model that more accurately captures the actual distorted in-plane geometry of nominally circular etch and lithography features. By accurately modeling the in-plane shape of hole shaped structures the fit between modelled and measured signals is improved along with more stable parametric tracking for deep structures such as DRAM and VNAND memory. By increasing the number of independent parameters employed to describe the in-plane shape of hole structures as described herein, the resulting geometric model fits the actual shape of the hole structure; including the shape errors induced by non-ideal lithographic and etch processes.

In general, X-ray scatterometry measurements of high aspect ratio structures are performed at one or more steps of a fabrication process flow. Exemplary process steps include etch, deposition, and lithography processes. The measurements are performed quickly and with sufficient accuracy to enable yield improvement of an on-going semiconductor fabrication process flow. High aspect ratio structures include sufficient overall scattering volume and material contrast to efficiently scatter incident x-rays. The collected, scattered x-rays enable accurate estimation of structural parameters of interest of measured devices. The x-ray energy is high enough to penetrate the silicon wafer and process gases in the optical path with minimal signal contamination.

Device yield of advanced semiconductor manufacturing nodes continues to suffer, particularly the device yield of complex, high aspect ratio (deep, three-dimensional) structures. Real-time monitoring and process control based on x-ray scatterometry enables process control for the fabrication of high aspect ratio structures in a cost effective manner compared to traditional destructive techniques such as SEM, TEM, etc.

X-ray scatterometry measurements provide accurate estimates of structural parameters of interest of high aspect ratio structures at high throughput without destroying the sample under measurement. Measurement sensitivity is not significantly affected by penetration depth, enabling accurate measurement of structures located deep within the vertical stack of the measured semiconductor structure.

In one aspect, a SAXS based measurement model includes a geometrically parameterized response model of one or more structures under measurement. The geometrically parameterized response model characterizes the in-plane shape of the measured structures with a geometric model having more than two degrees of freedom. In some embodiments, the one or more structures under measurement are deep hole structures fabricated by a series of lithographic and etch steps.

In some embodiments, the geometric model employed to characterize the in-plane shape of a measured hole structure at a particular depth includes a closed curve having three degrees of freedom or more, i.e., three or more independent parameters define the shape of the curve in a two dimensional plane. An example of a curve having three degrees of freedom is a curve defined by a third order function, e.g., a cubic spline. In some other embodiments, the geometric model employed to characterize the in-plane shape of a measured hole structure at a particular depth includes a closed curve comprising a piecewise assembly of two or more conic sections, e.g., elliptical, parabolic, hyperbolic sections. In these embodiments, each conic section is defined by at least one independent parameter, i.e., each conic section has at least one degree of freedom. Moreover, a piecewise assembly of conic sections defined by a total of more than two independent parameters, i.e., more than two degrees of freedom, is employed to describe the in-plane shape of one or more hole structures at a particular depth. For example, a piecewise assembly of four differently shaped elliptical curves may have up to eight independent parameters describing the closed curve, i.e., two independent parameters describing each of the four elliptical curves. Conic sections are examples of curves defined by a second order function, e.g., a quadratic function.

A closed curve comprising a piecewise assembly of curves defines a shape as an assembly of open curves; each endpoint of each open curve joined to an endpoint of another curve of the assembly to form the continuous, closed curve. In some embodiments, the slope at one or more of the endpoints is smooth, i.e., the first spatial derivative at the location where two curves are joined together is the same for both curves.

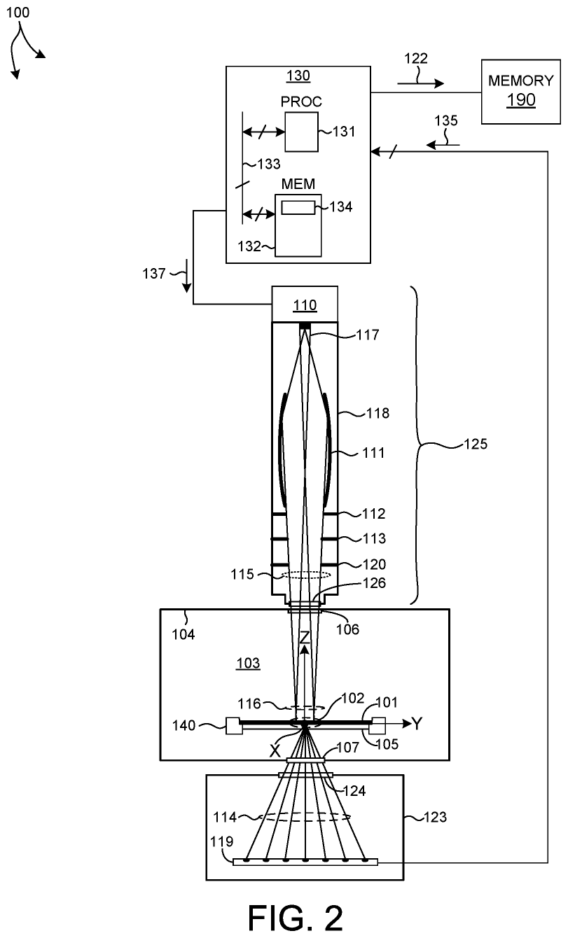

FIG. 2 depicts an exemplary wafer measurement system 100 to perform x-ray scatterometry measurements of semiconductor structures disposed on a wafer. In the depicted embodiment, the measurement system is a transmission, small-angle scatterometry (T-SAXS) metrology system. In some embodiments, the measured values of the parameters of interest 122 are provided as feedback to control a fabrication process tool, e.g., an etch process tool, a lithographic process tool, a deposition tool, etc.

Wafer measurement system 100 includes a vacuum chamber 104 containing a vacuum environment 103. Semiconductor wafer 101 is located within vacuum chamber 104. Wafer 101 is attached to wafer chuck 105 and is positioned with respect to the x-ray scatterometer by wafer stage 140.

In some embodiments, wafer stage 140 moves wafer 101 in the XY plane by combining a rotational movement with a translational movement (e.g., a translational movement in the X direction and a rotational movement about the Y-axis) to position wafer 101 with respect to the illumination provided by the x-ray scatterometer. In some other embodiments, wafer stage 140 combines two orthogonal, translational movements (e.g., movements in the X and Y directions) to position wafer 101 with respect to the illumination provided by the x-ray scatterometer. In some embodiments, wafer stage 140 is configured to control the position of wafer 101 with respect to the illumination provided by the x-ray scatterometer in six degrees of freedom. In general, specimen positioning system 140 may include any suitable combination of mechanical elements to achieve the desired linear and angular positioning performance, including, but not limited to goniometer stages, hexapod stages, angular stages, and linear stages.

In some embodiments, wafer measurement system 100 does not include wafer stage 140. In these embodiments, a wafer handling robot (not shown) locates wafer 101 on wafer chuck 105 inside vacuum chamber 104. Wafer 101 is transferred from the wafer handling robot onto an electrostatic wafer chuck 105 that is compatible with a vacuum environment 103. In these embodiments, the measurements performed by the x-ray scatterometer are limited to the portion of wafer 101 within the field of view of the x-ray scatterometer after clamping of wafer 101 onto wafer chuck 105. In this sense, wafer stage 140 is optional. To overcome this limitation, wafer measurement system 100 may include multiple x-ray scatterometer systems, each measuring a different area of wafer 101.

As depicted in FIG. 2, the optical elements of the x-ray scatterometer are located outside of the vacuum chamber 104. However, in some other embodiments, the optical elements of the x-ray scatterometer are located inside the vacuum chamber 104.

In the depicted embodiment, the SAXS metrology system includes an x-ray illumination subsystem 125 including an x-ray illumination source 110, focusing optics 111, beam divergence control slit 112, intermediate slit 113, and a beam shaping slit mechanism 120. The x-ray illumination source 110 is configured to generate x-ray radiation suitable for T-SAXS measurements. In some embodiments, the x-ray illumination source 110 is configured to generate wavelengths between 0.01 nanometers and 1 nanometer. In general, any suitable high-brightness x-ray illumination source capable of generating high brightness x-rays at flux levels sufficient to enable high-throughput, inline metrology may be contemplated to supply x-ray illumination for T-SAXS measurements. In some embodiments, an x-ray source includes a tunable monochromator that enables the x-ray source to deliver x-ray radiation at different, selectable wavelengths.

In some embodiments, one or more x-ray sources emitting radiation with photon energy greater than 15 keV, or greater than 17 keV, are employed to ensure that the x-ray source supplies light at wavelengths that allow sufficient transmission through the entire device as well as the wafer substrate, and any intervening elements. Intervening elements may include one or more windows (e.g., windows made from beryllium, sapphire, diamond, etc.). Intervening elements may also include structures in the path of the scattered x-ray radiation between the wafer 101 and detector 119, such as wafer chuck 105, a load port, or elements of stage 140. Transmission through structural plastic materials does not risk excessive contamination of the scattered signals. Apertures or windows through structural elements of wafer chuck 105, stage 140, or a load port may be employed to minimize signal contamination. For example, the x-ray spot at the wafer may be as small as 50-200 micrometers. For elements located close to the wafer, the size of the aperture required to minimize contamination of the scattered orders is minimal. However, the required aperture size increases as the distance from the wafer increases due to the finite scattering angles associated with the scattered orders of interest.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

By way of non-limiting example, x-ray illumination source 110 may include any of a particle accelerator source, a liquid anode source, a rotating anode source, a stationary, solid anode source, a microfocus source, a microfocus rotating anode source, a plasma based source, and an inverse Compton source. In one example, an inverse Compton source available from Lyncean Technologies, Inc., Palo Alto, Calif. (USA) may be contemplated. Inverse Compton sources have an additional advantage of being able to produce x-rays over a range of photon energies, thereby enabling the x-ray source to deliver x-ray radiation at different, selectable wavelengths.

In some examples, computing system 130 communicates command signals 137 to x-ray illumination source 110 that cause x-ray illumination source 110 to emit x-ray radiation at a desired energy level. The energy level is changed to acquire measurement data with more information about the high aspect ratio structures under measurement.

X-ray illumination source 110 produces x-ray emission over a source area having finite lateral dimensions (i.e., non-zero dimensions orthogonal to the beam axis. Focusing optics 111 focuses source radiation onto a metrology target located on specimen 101. The finite lateral source dimension results in finite spot size 102 on the target defined by the rays 117 coming from the edges of the source. In some embodiments, focusing optics 111 includes elliptically shaped focusing optical elements.

A beam divergence control slit 112 is located in the beam path between focusing optics 111 and beam shaping slit mechanism 120. Beam divergence control slit 112 limits the divergence of the illumination provided to the specimen under measurement. An additional intermediate slit 113 is located in the beam path between beam divergence control slit 112 and beam shaping slit mechanism 120. Intermediate slit 113 provides additional beam shaping. In general, however, intermediate slit 113 is optional.

Beam shaping slit mechanism 120 is located in the beam path before specimen 101. In some embodiments, beam shaping slit mechanism 120 includes multiple, independently actuated beam shaping slits. In one embodiment, beam shaping slit mechanism 120 includes four independently actuated beam shaping slits. These four beams shaping slits effectively block a portion of incoming beam 115 and generate an illumination beam 116 having a box shaped illumination cross-section.

In general, x-ray optics shape and direct x-ray radiation to specimen 101. In some examples, the x-ray optics include an x-ray monochromator to monochromatize the x-ray beam that is incident on the specimen 101. In some examples, the x-ray optics collimate or focus the x-ray beam onto measurement area 102 of specimen 101 to less than 1 milliradian divergence using multilayer x-ray optics. In these examples, the multilayer x-ray optics function as a beam monochromator, also. In some embodiments, the x-ray optics include one or more x-ray collimating mirrors, x-ray apertures, x-ray beam stops, refractive x-ray optics, diffractive optics such as zone plates, Montel optics, specular x-ray optics such as grazing incidence ellipsoidal mirrors, polycapillary optics such as hollow capillary x-ray waveguides, multilayer optics or systems, or any combination thereof. Further details are described in U.S. Patent Publication No. 2015/0110249, the content of which is incorporated herein by reference it its entirety.

In some embodiments, x-ray illumination source 110, focusing optics 111, slits 112 and 113, or any combination thereof, are maintained in a controlled atmospheric environment (e.g., gas purge environment). However, in some embodiments, the optical path length between and within any of these elements is long and x-ray scattering in air contributes noise to the image on the detector. Hence in some embodiments, any of x-ray illumination source 110, focusing optics 111, and slits 112 and 113 are maintained in a localized, vacuum environment. In the embodiment depicted in FIG. 2, focusing optics 111, slits 112 and 113, and beam shaping slit mechanism 120 are maintained in a controlled environment (e.g., vacuum) within an evacuated flight tube 118. The illumination beam 116 passes through window 122 at the end of flight tube 118 before incidence with window 106 of vacuum chamber 104. In some embodiments, flight tube 118 is integrated with vacuum chamber 104.

After incidence with wafer 101, scattered x-ray radiation 114 exits vacuum chamber 104 through window 107. In some embodiments, the optical path length between vacuum chamber 104 and detector 119 (i.e., the collection beam path) is long and x-ray scattering in air contributes noise to the image on the detector. Hence, in preferred embodiments, a significant portion of the collection beam path length between vacuum chamber 104 and detector 119 is maintained in a localized vacuum environment separated from the environment by a vacuum window (e.g., vacuum window 124). In some embodiments, vacuum chamber 123 is integrated with vacuum chamber 104 with a window separating the vacuum environment 103 from the vacuum environment maintained within vacuum chamber 123. In some embodiments, x-ray detector 119 is maintained in the same localized vacuum environment as the beam path length between vacuum chamber 104 and detector 119. For example, as depicted in FIG. 2, vacuum chamber 123 maintains a localized vacuum environment surrounding detector 119 and a significant portion of the beam path length between vacuum chamber 104 and detector 119.

In some other embodiments, x-ray detector 119 is maintained in a controlled atmospheric environment (e.g., gas purge environment). This may be advantageous to remove heat from detector 119. However, in these embodiments, it is preferable to maintain a significant portion of the beam path length between vacuum chamber 104 and detector 119 in a localized vacuum environment within a vacuum chamber. In general, the vacuum windows may be constructed of any suitable material that is substantially transparent to x-ray radiation (e.g., Kapton, Beryllium, etc.).

X-ray detector 119 collects x-ray radiation 114 scattered from specimen 101 and generates an output signals 135 indicative of properties of specimen 101 that are sensitive to the incident x-ray radiation in accordance with a T-SAXS measurement modality. In some embodiments, scattered x-rays 114 are collected by x-ray detector 119 while specimen positioning system 140 locates and orients specimen 101 to produce angularly resolved scattered x-rays.

In some embodiments, a T-SAXS system includes one or more photon counting detectors with high dynamic range (e.g., greater than 10⁵). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 119 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 130 via output signals 135 for further processing and storage (e.g., in memory 190).

In a further aspect, a T-SAXS system is employed to determine properties of a specimen (e.g., structural parameter values) based on one or more diffraction orders of scattered light. As depicted in FIG. 2, system 100 includes a computing system 130 employed to acquire signals 135 generated by detector 119 and determine properties of the specimen based at least in part on the acquired signals and store the determined parameters of interest 122 in a memory (e.g., memory 190). In some embodiments, computing system 130 is configured as a process control metrology engine to directly estimate values of one or more parameters of interest based on scatterometry measurements of wafers using a measurement model.

In another aspect, metrology based on T-SAXS involves determining the dimensions of the sample by the inverse solution of a pre-determined measurement model with the measured data. The measurement model includes a few (on the order of ten) adjustable parameters and is representative of the geometry and optical properties of the specimen and the optical properties of the measurement system. The method of inverse solve includes, but is not limited to, model based regression, tomography, machine learning, or any combination thereof. In this manner, target profile parameters are estimated by solving for values of a parameterized measurement model that minimize errors between the measured scattered x-ray intensities and modeled results.

In some embodiments, the measurement model is an electromagnetic model (e.g., a Born Wave Model) of the measurement that generates images representative of the scattering from the target under measurement. The modelled images may be parameterized by process control parameters (e.g., etch time, etch tilt, etch selectivity, deposition rate, etc.). The modelled images may also be parameterized by structural parameters of the measured high aspect ratio structure (e.g., height, diameter at different heights, alignment of a hole with respect to other structures, the straightness of a hole feature, the concentricity of a hole feature, thickness of deposited layers as a function of depth, uniformity of deposited layers across a particular hole feature or between different hole features, etc.).

The measured scattering images are employed to estimate values of one or more parameters of interest by performing an inverse solve. In these examples, an inverse solve would solve for values of process parameters, geometric parameters, or both, that generate modelled scattering images that most closely match measured images. In some examples, the space of scattering images is searched using the measurement model using regression methods (e.g., gradient descent, etc.). In some examples, a library of precomputed images is generated and the library is searched to find values of one or more of the parameters of interest that result in the best match between modelled and measured images.

In some other examples, a measurement model is trained by a machine learning algorithm to relate many samples of scattering images and known process conditions, geometric parameter values, or both. In this manner, the trained measurement model maps measured scattering images to estimated values of process parameters, geometric parameters, or both. In some examples, the trained measurement model is a signal response metrology (SRM) model that defines a direct, functional relationship between actual measurements and parameters of interest.

In general, any of the trained models described herein is implemented as a neural network model. In other examples, any of the trained models may be implemented as a linear model, a non-linear model, a polynomial model, a response surface model, a support vector machines model, a decision tree model, a random forest model, a deep network model, a convolutional network model, or other types of models.

In some examples, any of the trained models described herein may be implemented as a combination of models. Additional description of model training and the use of trained measurement models for semiconductor measurements is provided in U.S. Patent Publication No. 2016/0109230 by Pandev et al., the content of which is incorporated herein by reference in its entirety.

It is desirable to perform measurements at large ranges of angle of incidence and azimuth angle to increase the precision and accuracy of measured parameter values. This approach reduces correlations among parameters by extending the number and diversity of data sets available for analysis to include a variety of large-angle, out of plane orientations. For example, in a normal orientation, T-SAXS is able to resolve the critical dimension of a feature, but is largely insensitive to sidewall angle and height of a feature. However, by collecting measurement data over a broad range of out of plane angular orientations, the sidewall angle and height of a feature can be resolved. In other examples, measurements performed at large ranges of angle of incidence and azimuth angle provide sufficient resolution and depth of penetration to characterize high aspect ratio structures through their entire depth.

Measurements of the intensity of diffracted radiation as a function of x-ray incidence angle relative to the wafer surface normal are collected. Information contained in the multiple diffraction orders is typically unique between each model parameter under consideration. Thus, x-ray scattering yields estimation results for values of parameters of interest with small errors and reduced parameter correlation.

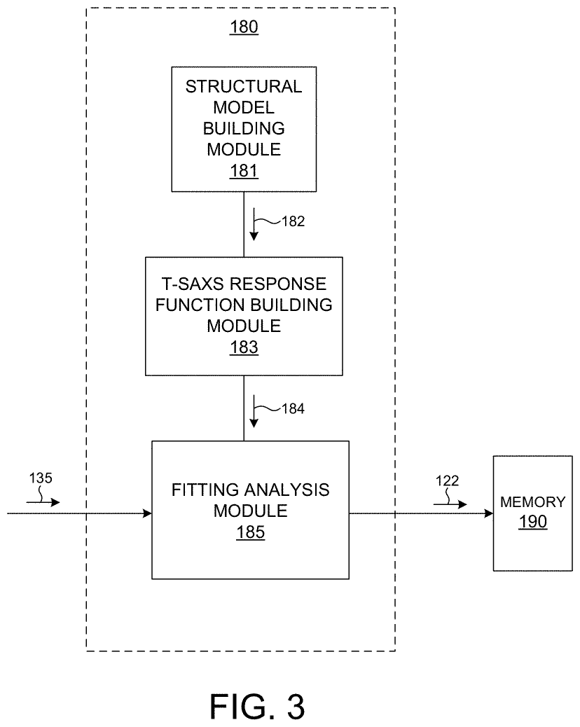

FIG. 3 is a diagram illustrative of an exemplary model building and analysis engine 180 implemented by computing system 130. As depicted in FIG. 3, model building and analysis engine 180 includes a structural model building module 181 that generates a structural model 182 of a measured structure of a specimen. In some embodiments, structural model 182 also includes material properties of the specimen. The structural model 182 is received as input to T-SAXS response function building module 183. T-SAXS response function building module 183 generates a T-SAXS response function model 184 based at least in part on the structural model 182. In some examples, the T-SAXS response function model 183 is based on x-ray form factors,

$$F ( \vec{q} ) = \int ρ ( \vec{r} ) {e}^{- i \vec{q} \cdot \vec{r}} d \vec{r} \qquad ( 3 )$$

where F is the form factor, q is the scattering vector, and ρ(r) is the electron density of the specimen in spherical coordinates. The x-ray scattering intensity is then given by

$$I ( \vec{q} ) = {F}^{*} F . \qquad ( 4 )$$

T-SAXS response function model 184 is received as input to fitting analysis module 185. The fitting analysis module 185 compares the modeled T-SAXS response with the corresponding measured data 135 to determine geometric as well as material properties of the specimen.

In some examples, the fitting of modeled data to experimental data is achieved by minimizing a chi-squared value. For example, for T-SAXS measurements, a chi-squared value can be defined as

$${χ}_{SAXS}^{2} = \frac{1}{{N}_{SAXS}} {\sum }_{j}^{{N}_{SAXS}} \frac{{( {S}_{j}^{SAXS model} ( {v}_{1} , … , {v}_{L} ) - {S}_{j}^{SAXS experiment} )}^{2}}{{σ}_{SAXS , j}^{2}} \qquad ( 5 )$$

Where, Sⱼ^{SAXS experiment} is the measured T-SAXS signals 126 in the “channel” j, where the index j describes a set of system parameters such as diffraction order, energy, angular coordinate, etc. Sⱼ^{SAXS model}(v₁, . . . , v_{L}) is the modeled T-SAXS signal Sⱼ for the “channel” j, evaluated for a set of structure (target) parameters v₁, . . . , v_{L}, where these parameters describe geometric (CD, sidewall angle, overlay, etc.) and material (electron density, etc.). σ_{SAXS,j} is the uncertainty associated with the jth channel. N_{SAXS} is the total number of channels in the x-ray metrology. L is the number of parameters characterizing the metrology target.

Equation (5) assumes that the uncertainties associated with different channels are uncorrelated. In examples where the uncertainties associated with the different channels are correlated, a covariance between the uncertainties, can be calculated. In these examples a chi-squared value for T-SAXS measurements can be expressed as

$${χ}_{SAXS}^{2} = \frac{1}{{N}_{SAXS}} {( {\vec{S}}_{j}^{SAXS . model} ( {v}_{1} , … , {v}_{M} ) - {\vec{S}}_{j}^{SAXS . experiment} )}^{T} {V}_{SAXS}^{- 1} ( {\vec{S}}_{j}^{SAXS . model} ( {v}_{1} , … , {v}_{M} ) - {\vec{S}}_{j}^{SAXS . experiment} ) \qquad ( 6 )$$

where, V_{SAXS} is the covariance matrix of the SAXS channel uncertainties, and T denotes the transpose.

In some examples, fitting analysis module 185 resolves at least one specimen parameter value by performing a fitting analysis on T-SAXS measurement data 135 with the T-SAXS response model 184. In some examples, χ_{SAXS}² is optimized.

As described hereinbefore, the fitting of T-SAXS data is achieved by minimization of chi-squared values. However, in general, the fitting of T-SAXS data may be achieved by other functions.

The fitting of T-SAXS metrology data is advantageous for any type of T-SAXS technology that provides sensitivity to geometric and/or material parameters of interest. Specimen parameters can be deterministic (e.g., CD, SWA, etc.) or statistical (e.g., rms height of sidewall roughness, roughness correlation length, etc.) as long as proper models describing T-SAXS beam interaction with the specimen are used.

In general, computing system 130 is configured to access model parameters in real-time, employing Real Time Critical Dimensioning (RTCD), or it may access libraries of pre-computed models for determining a value of at least one specimen parameter value associated with the specimen 101. In general, some form of CD-engine may be used to evaluate the difference between assigned CD parameters of a specimen and CD parameters associated with the measured specimen. Exemplary methods and systems for computing specimen parameter values are described in U.S. Pat. No. 7,826,071, issued on Nov. 2, 2010, to KLA-Tencor Corp., the entirety of which is incorporated herein by reference.

In some examples, model building and analysis engine 180 improves the accuracy of measured parameters by any combination of feed sideways analysis, feed forward analysis, and parallel analysis. Feed sideways analysis refers to taking multiple data sets on different areas of the same specimen and passing common parameters determined from the first dataset onto the second dataset for analysis. Feed forward analysis refers to taking data sets on different specimens and passing common parameters forward to subsequent analyses using a stepwise copy exact parameter feed forward approach. Parallel analysis refers to the parallel or concurrent application of a non-linear fitting methodology to multiple datasets where at least one common parameter is coupled during the fitting.

Multiple tool and structure analysis refers to a feed forward, feed sideways, or parallel analysis based on regression, a look-up table (i.e., “library” matching), or another fitting procedure of multiple datasets. Exemplary methods and systems for multiple tool and structure analysis is described in U.S. Pat. No. 7,478,019, issued on Jan. 13, 2009, to KLA-Tencor Corp., the entirety of which is incorporated herein by reference.

In another aspect, one or more SAXS systems are configured to measure multiple, different areas of a wafer. In some embodiments, a wafer uniformity value associated with each measured parameter of interest is determined based on measured values of each parameter of interest across the wafer.

In some embodiments, multiple metrology systems are integrated with the process tool and the metrology systems are configured to simultaneously measure different areas across the wafer during process. In some embodiments, a single metrology system integrated with a process tool is configured to sequentially measure multiple, different areas of a wafer during process.

In some embodiments, the methods and systems for SAXS based metrology of semiconductor devices as described herein are applied to the measurement of memory structures. These embodiments enable critical dimension (CD), film, and composition metrology for periodic and planar structures.

Scatterometry measurements as described herein may be used to determine characteristics of a variety of semiconductor structures. Exemplary structures include, but are not limited to, FinFETs, low-dimensional structures such as nanowires or graphene, sub 10 nm structures, lithographic structures, through substrate vias (TSVs), memory structures such as DRAM, DRAM 4F2, FLASH, MRAM and high aspect ratio memory structures. Exemplary structural characteristics include, but are not limited to, geometric parameters such as line edge roughness, line width roughness, pore size, pore density, side wall angle, profile, critical dimension, pitch, thickness, overlay, and material parameters such as electron density, composition, grain structure, morphology, stress, strain, and elemental identification. In some embodiments, the metrology target is a periodic structure. In some other embodiments, the metrology target is aperiodic.

In some examples, measurements of critical dimensions, thicknesses, overlay, and material properties of high aspect ratio semiconductor structures including, but not limited to, spin transfer torque random access memory (STT-RAM), three dimensional NAND memory (3D-NAND) or vertical NAND memory (V-NAND), dynamic random access memory (DRAM), three dimensional FLASH memory (3D-FLASH), resistive random access memory (Re-RAM), and phase change random access memory (PC-RAM) are performed with T-SAXS measurement systems as described herein.

In some examples, the measurement models are implemented as an element of a SpectraShape® critical-dimension metrology system available from KLA-Tencor Corporation, Milpitas, Calif., USA. In this manner, the model is created and ready for use immediately after the scattering images are collected by the system.

In some other examples, the measurement models are implemented off-line, for example, by a computing system implementing AcuShape® software available from KLA-Tencor Corporation, Milpitas, Calif., USA. The resulting models may be incorporated as an element of an AcuShape® library that is accessible by a metrology system performing measurements.

In some embodiments, the geometric model employed to characterize the in-plane shape of a measured hole structure at a particular depth includes a closed curve having three or more degrees of freedom, i.e., three or more independent parameters define the shape of the curve in a two dimensional plane, an example of which is illustrated by equations (7A)-(7B). As illustrated in equations (7A)-(7B), the model of an in-plane hole shape, e.g., a second order circular function, includes four degrees of freedom, i.e., four independent parameters employed to determine the shape described by the function. The four independent parameters include nominal radius, r, first order eccentricity, e, second order eccentricity eₓ, and second order eccentricity, e_{y}.

$$\begin{matrix}x = r ( e cos θ + {e}_{x}^{2} {cos}^{2} θ ) & ( 7 A ) \\ y = r ( sin θ + {e}_{y}^{2} {sin}^{2} θ ) & ( 7 B )\end{matrix}$$

By increasing the parameterization of the in-plane shape to four degrees of freedom, the shape described by the closed curve may be slightly distorted.

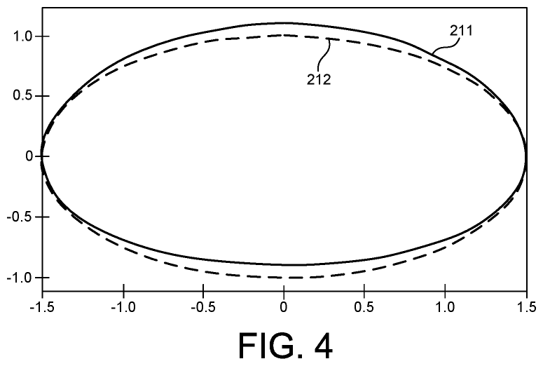

FIG. 4 depicts shapes described by an ellipse function and a second order circular function in one example. Plotline 210 illustrates a shape described by an ellipse function illustrated by equations (2A)-(2B) having non-zero values of two degrees of freedom, r and e. Plotline 211 illustrates a shape described by a second order circular function in the y-direction illustrated by equations (7A)-(7B) having non-zero values of r, e, and e_{y}. As depicted in FIG. 4, the shape described by the second order circular function is distorted in the y-direction.

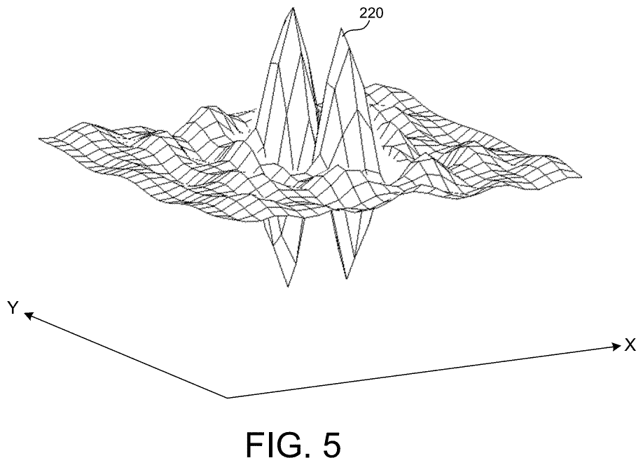

FIG. 5 depicts a three dimensional plot of signal error at the detector in one example. In the example depicted in FIG. 5, the signal error is determined as a weighted difference between measured signals at the detector and modelled signals using an ellipse function model of hole shape. The weighting is a logarithm function. The logarithm function normalizes the error signals across the detector. In general, this emphasizes errors of strongly scattered orders, i.e., signals farther from the center of the detector, and de-emphasizes lower order errors, i.e., errors closer to the center of the detector. As depicted in FIG. 5, significant errors exist at lower scattering orders, but also at higher orders where valuable shape information tends to be located. These errors indicate a poor match between measured and modelled intensities at the detector.

In some other embodiments, the geometric model employed to characterize the in-plane shape of a measured hole structure at a particular depth includes a piecewise assembly of two or more conic sections, e.g., elliptical, parabolic, hyperbolic sections.

In one example, the distorted ellipse described by the second order circular function illustrated by equations (7A)-(7B) is closely approximated by piecewise assembly of four purely elliptical quadrants, each with its own radial and elliptical parameters. Their linear parameters can be determined by the parametric constants weighting the non-linear terms in equations (7A)-(7B) as illustrated by equations (8A)-(8B), (9A)-(9B), (10A)-(10B), and (11A)-(11B).

For the northeast quadrant, i.e., θ from 0 degrees to 90 degrees measured counterclockwise from the x-axis,

$$\begin{matrix}x = r ( e + {e}_{x}^{2} ) cos θ & ( 8 A ) \\ y = r ( 1 + {e}_{y}^{2} ) sin θ & ( 8 B )\end{matrix}$$

For the northwest quadrant, i.e., θ from 90 degrees to 180 degrees measured counterclockwise from the x-axis,

$$\begin{matrix}x = r ( e - {e}_{x}^{2} ) cos θ & ( 9 A ) \\ y = r ( 1 + {e}_{y}^{2} ) sin θ & ( 9 B )\end{matrix}$$

For the southwest quadrant, i.e., θ from 180 degrees to 270 degrees measured counterclockwise from the x-axis,

$$\begin{matrix}x = r ( e - {e}_{x}^{2} ) cos θ & ( 10 A ) \\ y = r ( 1 - {e}_{y}^{2} ) sin θ & ( 10 B )\end{matrix}$$

For the southeast quadrant, i.e., θ from 270 degrees to 360 degrees measured counterclockwise from the x-axis,

$$\begin{matrix}x = r ( e + {e}_{x}^{2} ) cos θ & ( 11 A ) \\ y = r ( 1 - {e}_{y}^{2} ) sin θ & ( 11 B )\end{matrix}$$

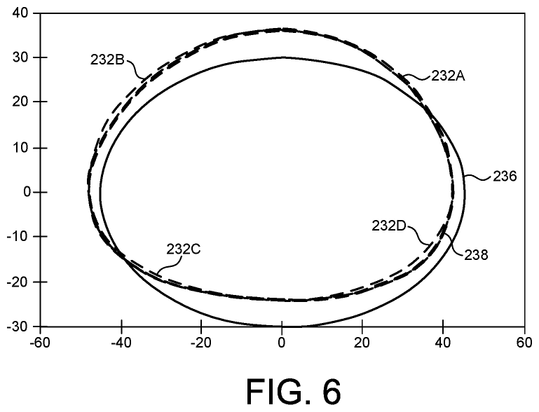

FIG. 6 depicts shapes described by an ellipse function, a second order circular function, and piecewise assembly of four conic sections in one example. Plotline 230 illustrates a shape described by a first order circular function illustrated by equations (2A)-(2B) having non-zero values of two degrees of freedom, r and e. Plotline 231 illustrates a shape described by a second order circular function in the y-direction illustrated by equations (7A)-(7B) having non-zero values of r, e, and e_{y}. Plotlines 232A-D illustrate a piecewise assembly of four elliptical sections each described by a different first order elliptical function. Plotline 232A is described by equations (8A)-(8B), plotline 232B is described by equations (9A)-(9B), plotline 232C is described by equations (10A)-(10B), and plotline 232D is described by equations (11A)-(11B) for non-zero values of r, e, eₓ, and e_{y}. As depicted in FIG. 6, the shape described by the piecewise assembly of elliptical functions closely matches the shape described by the second order circular function. Moreover, the shape described by the piecewise assembly of elliptical functions is approximately a 20% distortion of the shape described by the first order circular function.

In general, the independent parameters describing an in-plane hole shape are expressed as functions of depth through the structure, i.e., z-direction, to describe the real variation of in-plane shape of processed semiconductor devices as a function of depth. In a typical patterning process, holes in resist are approximately circular with minimal or very small distortion. However, the process control of an etch tool is limited. As a result, the distortion changes with depth as the etch process transfers the lithographic pattern to the semiconductor layer. The ability to accurately describe the shape variation as function of depth leads to a more accurate fit between model and measured data, and consequently, improved estimates of shape parameter values.

The aforementioned parameterization employed to describe elliptical curves is described in terms of radius, and linear eccentricity, and quadratic eccentricity parameters. However, in general, other parameterizations may be employed to describe elliptical curves with the same results, and such parameterizations are contemplated within the scope of this patent document. By way of non-limiting example, parameterization by major and minor axis parameters, are contemplated within the scope of this patent document.

Although, the aforementioned parameterization of elliptical distortion is described in terms of second order elliptical terms, in general, higher order terms are contemplated within the scope of this patent document. However, the mathematics of power law approximations and etching physics suggest that the magnitude of the contribution of the parameterization to describe a shape drops proportionally with the order of the error. Thus, second order distortion captures more in-plane shape variation than higher orders, and so forth.

In general, any arbitrary translation and rotation of any in-plane shape employed to describe a measured structure is contemplated within the scope of this patent document. By way of non-limiting example, elliptical axes may be rotated using Given's rotation. Similarly, elliptical axes may be shifted such that the ellipse is located at any location in a Cartesian plane.

In general, higher order distortions can be equivalently described by piecewise assembly of any number of conic sections, e.g., elliptical sections. For example, three or six elliptical sections may be employed to describe a triangular shaped hole structure. In another example, eight elliptical sections may be employed to describe a square or octagonal shaped hole structure. As such, it is contemplated within this patent document that any number of conic sections greater than one may be adjoined to describe the shape of a measured structure.

The advantage of a piecewise assembly of conic sections to approximate the shape of a measured structure is that all curves have known analytical formulas for intersections with other conic sections or linear curves. The available analytical solutions are compatible with computations already performed by the AcuShape® software available from KLA-Tencor Corporation, Milpitas, Calif., USA.

Conversely, a difficulty arising from the use of second order or higher order descriptions of curves is that the computation of intersection points between second order or higher order curves requires a numerical solution, which increases the computational burden of the model.

In general, a metrology target is characterized by an aspect ratio defined as a maximum height dimension (i.e., dimension normal to the wafer surface) divided by a maximum lateral extent dimension (i.e., dimension aligned with the wafer surface) of the metrology target. In some embodiments, the metrology target under measurement has an aspect ratio of at least twenty. In some embodiments, the metrology target has an aspect ratio of at least forty.

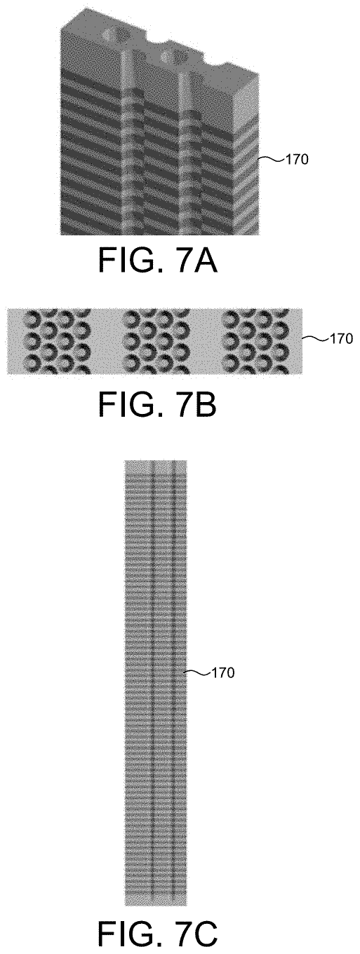

FIGS. 7A-7C depict an isometric view, a top view, and a cross-sectional view, respectively, of a typical 3D FLASH memory device 170 subject to measurement in the manner described herein. The total height (or equivalently depth) of memory device 170 ranges from one to several micrometers. Memory device 170 is a vertically manufactured device. A vertically manufactured device, such as memory device 170, essentially turns a conventional, planar memory device 90 degrees, orienting the bit line and cell string vertically (perpendicular to wafer surface). To provide sufficient memory capacity, a large number of alternating layers of different materials are deposited on the wafer. This requires patterning processes to perform well to depths of several microns for structures with a maximum lateral extent of one hundred nanometers or less. As a result, aspect ratios of 25 to 1 or 50 to 1 are not uncommon.

In another aspect, process corrections are determined based on the measured values of the parameters of interest (e.g., critical dimension, overlay, height, sidewall angle, etc.) and the corrections are communicated to the process tool to change one or more process control parameters of the process tool (e.g., lithography tool, etch tool, deposition tool, etc.). In some embodiments, SAXS measurements are performed and process control parameters are updated while the process is being executed on the measured structure. In some embodiments, SAXS measurements are performed after a particular process step and process control parameters associated with that process step are updated for processing of future devices by that process step. In some embodiments, SAXS measurements are performed after a particular process step and process control parameters associated with a subsequent process step are updated for processing of the measured device or other devices by the subsequent process step.

In some examples, values of measured parameters determined based on measurement methods described herein can be communicated to an etch tool to adjust the etch time to achieve a desired etch depth. In a similar way etch parameters (e.g., etch time, diffusivity, etc.) or deposition parameters (e.g., time, concentration, etc.) may be included in a measurement model to provide active feedback to etch tools or deposition tools, respectively. In some examples, corrections to process parameters determined based on measured device parameter values may be communicated to the process tool. In one embodiment, computing system 130 determines values of one or more parameters of interest during process based on measured signals 135 received from metrology system 101. In addition, computing system 130 communicates control commands to a process controller based on the determined values of the one or more parameters of interest. The control commands cause the process controller to change the state of the process (e.g., stop the etch process, change the diffusivity, etc.). In one example, a control command causes a process controller to stop the etch process when a desired etch depth is measured. In another example, a control command causes a process controller to change etch rate to improve measured wafer uniformity of a CD parameter.

Although, FIG. 2 depicts a transmission SAXS measurement system, in general, a reflective SAXS measurement system may be employed to measure features as described herein.

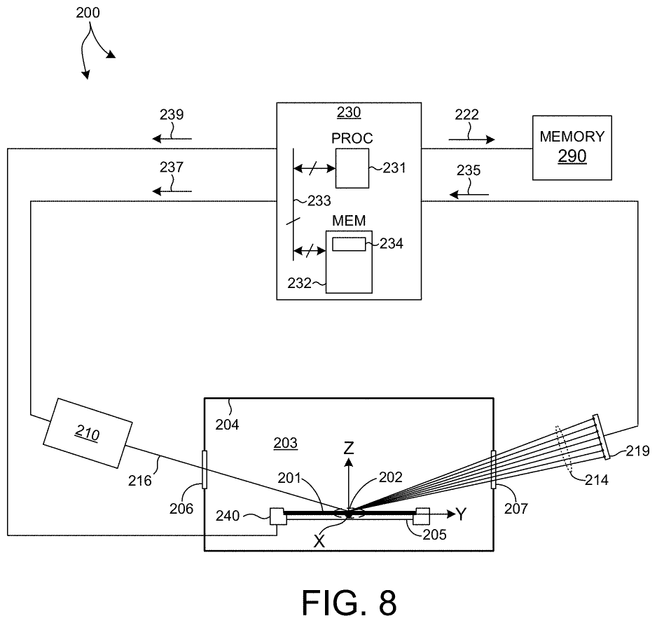

FIG. 8 depicts an exemplary wafer measurement system 200 for x-ray scatterometry measurements of semiconductor structures. In some embodiments, the measured values of the parameters of interest 222 are provided as feedback to control a fabrication process tool, e.g., an etch process tool, a lithographic process tool, a deposition tool, etc.

Wafer measurement system 200 includes a vacuum chamber 204 containing a vacuum environment 203 and a reflective x-ray scatterometer. Semiconductor wafer 201 is located within vacuum chamber 204. Wafer 201 is attached to wafer chuck 205 and is positioned with respect to vacuum chamber 204 and the x-ray scatterometer by wafer stage 240.

In the depicted embodiment, the SAXS metrology system includes an x-ray illumination source 210 configured to generate x-ray radiation suitable for reflective SAXS measurements analogous to the description of illumination source 110 with reference to FIG. 2.

In some examples, computing system 130 communicates command signals 237 to x-ray illumination source 210 that cause x-ray illumination source 210 to emit x-ray radiation at a desired energy level. The energy level is changed to acquire measurement data with more information about the high aspect ratio structures under measurement.

The illumination beam 216 passes through window 206 of vacuum chamber 204 and illuminates specimen 201 over a measurement spot 201. After incidence with wafer 201, scattered x-ray radiation 214 exits vacuum chamber 204 through window 207. In some embodiments, the optical path length between vacuum chamber 204 and detector 219 (i.e., the collection beam path) is long and x-ray scattering in air contributes noise to the image on the detector. Hence, in preferred embodiments, a significant portion of the collection beam path length between vacuum chamber 204 and detector 219 is maintained in a localized vacuum environment.

X-ray detector 219 collects x-ray radiation 214 scattered from specimen 201 and generates output signals 235 indicative of properties of specimen 201 that are sensitive to the incident x-ray radiation in accordance with a reflective SAXS measurement modality. In some embodiments, scattered x-rays 214 are collected by x-ray detector 219 while specimen positioning system 240 locates and orients specimen 201 to produce angularly resolved scattered x-rays in accordance with command signals 239 communicated from computing system 230 to specimen positioning system 240.

In a further aspect, computing system 230 is employed to determine properties of wafer 201 (e.g., structural parameter values) based on one or more diffraction orders of scattered light. As depicted in FIG. 8, system 200 includes a computing system 230 employed to acquire signals 235 generated by detector 219 and determine properties of the specimen based at least in part on the acquired signals, and store an indication 222 of the determined values of the parameters of interest in a memory (e.g., memory 290). In some embodiments, computing system 230 is configured as a process control metrology engine to directly estimate values of one or more parameters of interest based on scatterometry measurements of wafers under process using a measurement model as described herein.

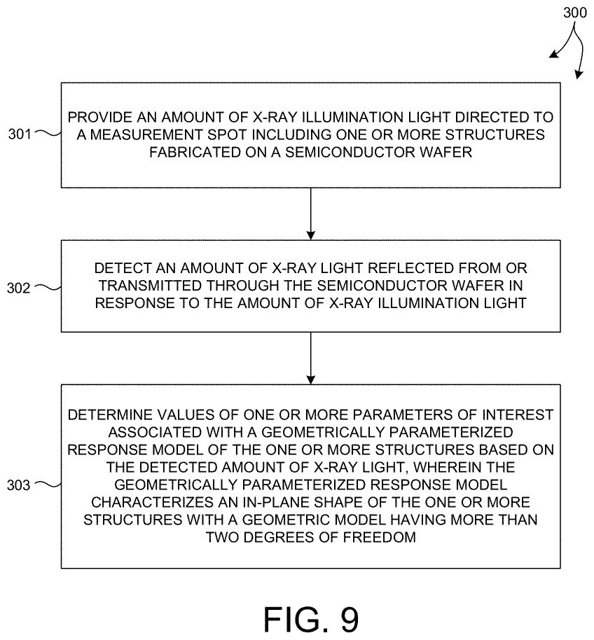

FIG. 9 illustrates a method 300 of performing metrology measurements of high aspect ratio structures in at least one novel aspect. Method 300 is suitable for implementation by a metrology system such as the SAXS metrology systems illustrated in FIGS. 2 and 8 of the present invention. In one aspect, it is recognized that data processing blocks of method 300 may be carried out via a pre-programmed algorithm executed by one or more processors of computing system 130, computing system 230, or any other general purpose computing system. It is recognized herein that the particular structural aspects of the metrology systems depicted in FIGS. 2 and 8 do not represent limitations and should be interpreted as illustrative only.

In block 301, an amount of x-ray illumination light is directed to a measurement spot including one or more structures fabricated on a semiconductor wafer.

In block 302, an amount of x-ray light reflected from or transmitted through the semiconductor wafer is detected in response to the amount of x-ray illumination light.

In block 303, values of one or more parameters of interest associated with a geometrically parameterized response model of the one or more structures are determined based on the detected amount of x-ray light. The geometrically parameterized response model characterizes an in-plane shape of the one or more structures with a geometric model having more than two degrees of freedom.

In a further embodiment, system 100 includes one or more computing systems 130 employed to perform measurements of semiconductor structures based on scatterometry measurement data collected in accordance with the methods described herein. The one or more computing systems 130 may be communicatively coupled to one or more detectors, active optical elements, process controllers, etc. In one aspect, the one or more computing systems 130 are configured to receive measurement data associated with scatterometry measurements of structures of wafer 101.

It should be recognized that one or more steps described throughout the present disclosure may be carried out by a single computer system 130 or, alternatively, a multiple computer system 130. Moreover, different subsystems of system 100 may include a computer system suitable for carrying out at least a portion of the steps described herein. Therefore, the aforementioned description should not be interpreted as a limitation on the present invention but merely an illustration.

In addition, the computer system 130 may be communicatively coupled to the spectrometers in any manner known in the art. For example, the one or more computing systems 130 may be coupled to computing systems associated with the scatterometers. In another example, the scatterometers may be controlled directly by a single computer system coupled to computer system 130.

The computer system 130 of system 100 may be configured to receive and/or acquire data or information from the subsystems of the system (e.g., scatterometers and the like) by a transmission medium that may include wireline and/or wireless portions. In this manner, the transmission medium may serve as a data link between the computer system 130 and other subsystems of system 100.

Computer system 130 of system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board system 100, external memory, or other external systems). For example, the computing system 130 may be configured to receive measurement data from a storage medium (i.e., memory 132 or an external memory) via a data link. For instance, scattered images obtained using the scatterometers described herein may be stored in a permanent or semi-permanent memory device (e.g., memory 132 or an external memory). In this regard, the scatterometry images may be imported from on-board memory or from an external memory system. Moreover, the computer system 130 may send data to other systems via a transmission medium. For instance, a measurement model or an estimated parameter value determined by computer system 130 may be communicated and stored in an external memory. In this regard, measurement results may be exported to another system.

Computing system 130 may include, but is not limited to, a personal computer system, mainframe computer system, workstation, image computer, parallel processor, or any other device known in the art. In general, the term “computing system” may be broadly defined to encompass any device having one or more processors, which execute instructions from a memory medium.

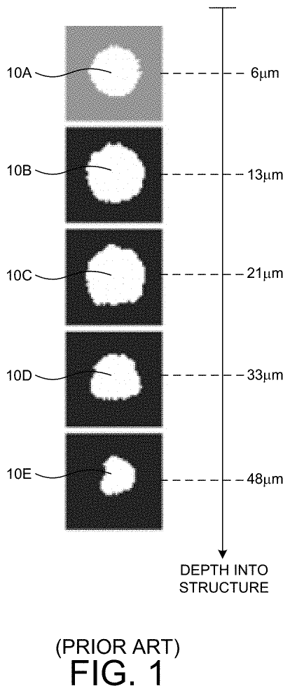

Program instructions 134 implementing methods such as those described herein may be transmitted over a transmission medium such as a wire, cable, or wireless transmission link. For example, as illustrated in FIG. 1, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape. Computing system 230, including elements 231-234, is analogous to computing system 130, including elements 131-134, respectively, as described herein.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on critical dimension data.

Various embodiments are described herein for a semiconductor measurement system that may be used for measuring a specimen within any semiconductor processing tool (e.g., an inspection system or a lithography system). The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
providing an amount of x-ray illumination light directed to a measurement spot including one or more structures fabricated on a semiconductor wafer;
detecting an amount of x-ray light reflected from or transmitted through the semiconductor wafer in response to the amount of x-ray illumination light;
determining values of one or more parameters of interest associated with a geometrically parameterized response model of the one or more structures based on the detected amount of x-ray light, wherein the geometrically parameterized response model characterizes an in-plane shape of the one or more structures with a geometric model having more than two degrees of freedom.

2. The method of claim 1, wherein the determining of the values of the one or more parameters of interest involves a fitting analysis of the detected amount of x-ray light with the geometrically parameterized response model.

3. The method of claim 1, wherein the geometric model includes a closed curve having a shape defined in a two dimensional plane by three of more independent parameters.

4. The method of claim 1, wherein the geometric model includes a closed curve comprising a piecewise assembly of two or more conic sections.

5. The method of claim 4, wherein the piecewise assembly of two or more conic sections includes a plurality of elliptical sections, each of the plurality of elliptical sections described by independent radial and ellipticity parameters.

6. The method of claim 4, wherein the piecewise assembly of two or more conic sections includes a plurality of parabolic sections each described by two independent parameters.

7. The method of claim 1, wherein the one or more structures includes a three-dimensional NAND structure or a dynamic random access memory (DRAM) structure.

8. The method of claim 1, wherein the values of the one or more parameters of interest are determined at a process step of a fabrication process flow of the one or more structures, and wherein an indication of the values of the one or more parameters of interest is communicated to the fabrication tool that causes the fabrication tool to adjust a value of one or more process control parameters of the fabrication tool at the process step.

9. The method of claim 1, wherein independent values of the geometric model vary as a function of depth into the one or more structures under measurement.

10. The method of claim 1, wherein the amount of x-ray illumination light is directed to the measurement spot at a plurality of angles of incidence, azimuth angles, or both.

11. The method of claim 1, wherein the amount of x-ray illumination light is directed to the measurement spot at a plurality of different energy levels.

12. A system comprising:
an illumination source configured to provide an amount of x-ray illumination light directed to a measurement spot including one or more structures fabricated on a semiconductor wafer;
a detector configured to detect an amount of x-ray light reflected from or transmitted through the semiconductor wafer in response to the amount of x-ray illumination light; and
a computing system configured to determine values of one or more parameters of interest based on a fitting analysis of the detected amount of x-ray light with a geometrically parameterized response model of the one or more structures, wherein the geometrically parameterized response model characterizes an in-plane shape of the one or more structures with a geometric model having more than two degrees of freedom.

13. The system of claim 12, wherein the geometric model includes a closed curve having a shape defined in a two dimensional plane by three of more independent parameters.

14. The system of claim 12, wherein the geometric model includes a closed curve comprising a piecewise assembly of two or more conic sections.

15. The system of claim 14, wherein the piecewise assembly of two or more conic sections includes a plurality of elliptical sections, each of the plurality of elliptical sections described by independent radial and ellipticity parameters.

16. The system of claim 14, wherein the piecewise assembly of conic sections includes a plurality of parabolic sections each described by two independent parameters.

17. The system of claim 12, wherein the one or more structures includes a three-dimensional NAND structure or a dynamic random access memory (DRAM) structure.

18. The system of claim 12, wherein the values of the one or more parameters of interest are determined at a process step of a fabrication process flow of the one or more structures, and wherein an indication of the values of the one or more parameters of interest is communicated to the fabrication tool that causes the fabrication tool to adjust a value of one or more process control parameters of the fabrication tool at the process step.

19. The system of claim 12, wherein independent values of the geometric model vary as a function of depth into the one or more structures under measurement.

20. A system comprising:
an illumination source configured to provide an amount of x-ray illumination light directed to a measurement spot including one or more structures fabricated on a semiconductor wafer;
a detector configured to detect an amount of x-ray light reflected from or transmitted through the semiconductor wafer in response to the amount of x-ray illumination light; and
a non-transient, computer-readable medium storing instructions that, when executed by one or more processors, causes the one or more processors to determine values of one or more parameters of interest based on a fitting analysis of the detected amount of x-ray light with a geometrically parameterized response model of the one or more structures, wherein the geometrically parameterized response model characterizes an in-plane shape of the one or more structures with a geometric model having more than two degrees of freedom.
